(19) United States
(12) Patent Application Publication
(10) Pub. No.: US 2025/0318441 A1
(43) Pub. Date: Oct. 9, 2025

(54) MAGNETIC MEMORY DEVICES

(71) Applicant: Samsung Electronics Co., Ltd., Suwon-si (KR)

(72) Inventors: Sungchul Lee, Suwon-si (KR); Kyungjin Lee, Daejeon-si (KR); Seokjong Kim, Daejeon-si (KR)

(73) Assignee: Korea Advanced Institute Of Science And Technology, Daejeon (KR)

(21) Appl. No.: 18/953,195

(22) Filed: Nov. 20, 2024

(30) Foreign Application Priority Data
Apr. 8, 2024 (KR) 10-2024-0047463

(51) Int. Cl. H10N 50/85; G11C 11/16; H10N 50/10; H10N 52/80

(52) U.S. Cl. CPC H10N 50/85; G11C 11/161; H10N 50/10; H10N 52/80

(57) ABSTRACT

A magnetic memory device comprising: a free magnetic layer configured to switch a direction of magnetization between first and second directions opposite to each other; a first insulation layer on the free magnetic layer; a ferroelectric layer on side surfaces of the free magnetic layer; and a non-magnetic conductive layer on the lower surface of the free magnetic layer, wherein the magnetic memory device further comprises a power supply configured to supply power to generate an in-plane current, the non-magnetic conductive layer is configured to generate a spin current in the first or the second direction from the in-plane current, an upper surface of the ferroelectric layer is coplanar with the upper surface of the free magnetic layer, and a lower surface of the ferroelectric layer is not coplanar with the lower surface of the free magnetic layer, and an electric polarization of the ferroelectric layer is a third direction.

### CROSS-REFERENCE TO RELATED APPLICATIONS

This application is based on and claims priority under 35 U.S.C. § 119 to Korean Patent Application No. 10-2024-0047463, filed on Apr. 8, 2024, in the Korean Intellectual Property Office, the disclosure of which is incorporated by reference herein in its entirety.

### BACKGROUND OF THE INVENTION

The inventive concept relates to magnetic memory devices, and more particularly, to magnetic memory devices using spin-orbit torque (SOT).

Research is being conducted on electronic devices that utilize the magnetoresistance properties of magnetic tunnel junction (MTJ). In particular, as MTJ cells of highly integrated magnetic random access memory (MRAM) devices become finer, SOT-MRAM, which stores information through a physical phenomenon called SOT by applying a current to a non-magnetic layer, is being studied. Highly integrated SOT-MRAM may need fast switching and low current operation.

### SUMMARY OF THE INVENTION

The inventive concept may provide magnetic memory devices with improved reliability.

According to an aspect of the inventive concept, there is provided a magnetic memory device including a free magnetic layer configured to switch a direction of magnetization between a first direction and a second direction that are opposite to each other, wherein the first direction and the second direction are perpendicular to an upper surface and/or a lower surface of the free magnetic layer; a first insulation layer on the free magnetic layer; a ferroelectric layer on at least a portion of side surfaces of the free magnetic layer; and a non-magnetic conductive layer on the lower surface of the free magnetic layer, wherein the magnetic memory device further comprises a power supply configured to supply power to the non-magnetic conductive layer to generate an in-plane current, wherein the non-magnetic conductive layer is configured to generate a spin current in the first direction by a spin hall effect from the in-plane current, wherein an upper surface of the ferroelectric layer is coplanar with the upper surface of the free magnetic layer, and a lower surface of the ferroelectric layer is not coplanar with the lower surface of the free magnetic layer, and wherein an electric polarization direction of the ferroelectric layer is a third direction parallel with the upper surface and/or the lower surface of the free magnetic layer.

According to another aspect of the inventive concept, there is provided a magnetic memory device including a non-magnetic conductive layer extending in a first direction and comprising a material having a spin hall effect; a power supply on a lower surface of the non-magnetic conductive layer, configured to supply power for generating an in-plane current to the non-magnetic conductive layer, and comprising a first electrode; a magnetic tunnel junction (MTJ) structure on at least a portion of an upper surface of the non-magnetic conductive layer; and a ferroelectric layer on at least a portion of side surfaces of the MTJ structure, wherein the non-magnetic conductive layer is configured to generate a spin current in a second direction by a spin hall effect from the in-plane current, wherein the first direction is parallel with the lower surface of the non-magnetic conductive layer, and the second direction is perpendicular to the lower surface of the non-magnetic conductive layer, wherein the MTJ structure comprises: a free magnetic layer on the non-magnetic conductive layer; and a first insulation layer on the free magnetic layer, wherein an electric polarization direction of the ferroelectric layer is a third direction perpendicular to the first direction and the second direction, wherein the free magnetic layer is configured to have a magnetization direction that is switched in the second direction and a fourth direction opposite to the second direction by a lateral magnetization and the spin current, and wherein the ferroelectric layer and the free magnetic layer are configured to cause the lateral magnetization therebetween by a surface magnetoelectric effect.

According to another aspect of the inventive concept, there is provided a magnetic memory device including a non-magnetic conductive layer extending in a first direction and comprising a material having a spin hall effect; a power supply on a lower surface of the non-magnetic conductive layer, configured to supply power for generating an in-plane current to the non-magnetic conductive layer, and comprising a first electrode; a magnetic tunnel junction (MTJ) structure on at least a portion of an upper surface of the non-magnetic conductive layer; and a ferroelectric layer on at least a portion of side surfaces of the MTJ structure, wherein the non-magnetic conductive layer is configured to generate a spin current in a second direction by a spin hall effect from the in-plane current, wherein the first direction is parallel with the lower surface of the non-magnetic conductive layer, and the second direction is perpendicular to the lower surface of the non-magnetic conductive layer, the MTJ structure comprises: a free magnetic layer on the non-magnetic conductive layer; and a first insulation layer on the free magnetic layer, wherein an electric polarization direction of the ferroelectric layer is a third direction perpendicular to the first direction and the second direction, wherein the free magnetic layer is configured to have a magnetization direction that is switched in the second direction and a fourth direction opposite to the second direction by a lateral magnetization and the spin current, wherein the ferroelectric layer and the free magnetic layer are configured to cause the lateral magnetization therebetween by a surface magnetoelectric effect, wherein the ferroelectric layer is spaced apart from an upper surface of the non-magnetic conductive layer in the second direction, wherein the magnetic memory device further comprises a second insulation layer between the ferroelectric layer and the non-magnetic conductive layer, wherein the second insulation layer extends around side surfaces of the free magnetic layer, and wherein a thickness of the second insulation layer in the second direction is less than a thickness of each of the free magnetic layer and the ferroelectric layer in the second direction.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a magnetic memory device according to some embodiments.

FIG. 2 is an enlarged perspective view of a region A of FIG. 1.

FIG. 3 is a perspective view of a magnetic memory device according to some embodiments.

FIG. 4 is a plan view of a magnetic memory device according to some embodiments.

FIG. 5 is a plan view of a magnetic memory device according to some embodiments.

FIG. 6 is a plan view of a magnetic memory device according to some embodiments.

FIG. 7 is a diagram showing the direction of magnetization of a free magnetic layer included in a magnetic memory device according to some embodiments.

FIG. 8 is a diagram showing the direction of magnetization of a free magnetic layer included in a magnetic memory device according to some embodiments.

FIG. 9 is a graph showing an average value of values obtained by calculating an average value of a vertical component of magnetization after field-free switching according to the magnitude of the DMI 100 times.

FIGS. 10A, 10B, 10C, 10D, and 10E are diagrams showing the direction of magnetization of a free magnetic layer included in a magnetic memory device according to some embodiments.

FIG. 11 is a block diagram showing an information processing system including a magnetic memory device according to some embodiments.

FIG. 12 is a block diagram showing an electronic system including a magnetic memory device according to some embodiments.

FIG. 13 is a block diagram showing a memory card including a magnetic memory device according to some embodiments.

### DETAILED DESCRIPTION OF THE INVENTION

Unless otherwise specified below, in this specification, a vertical direction may be defined as Z direction (+Z direction and/or −Z direction), and a first horizontal direction and a second horizontal direction may be defined as horizontal directions perpendicular to Z direction, respectively. The first horizontal direction may be referred to as X direction (+X direction and/or −X direction), and the second horizontal direction may be referred to as Y direction (+Y direction and/or −Y direction). Herein, Z direction refers to +Z direction and/or −Z direction, X direction refers to +X direction and/or −X direction, and Y direction refers to +Y direction and/or −Y direction unless clearly specified or stated otherwise. The first horizontal direction may intersect with (may be perpendicular to) the second horizontal direction. A vertical level may refer to a height level (or a distance) in the vertical direction (Z direction). For example, a vertical level of element A on element B may be a distance between element A and element B in the vertical direction. A higher vertical level may refer to a farther distance in the vertical direction. A lower vertical level may refer to a closer distance in the vertical direction. A horizontal width may refer to a length in a horizontal direction (X direction or Y direction), and a vertical length may refer to a length in the vertical direction (Z direction). As used herein, the term “and/or” includes any and all combinations of one or more of the associated listed items.

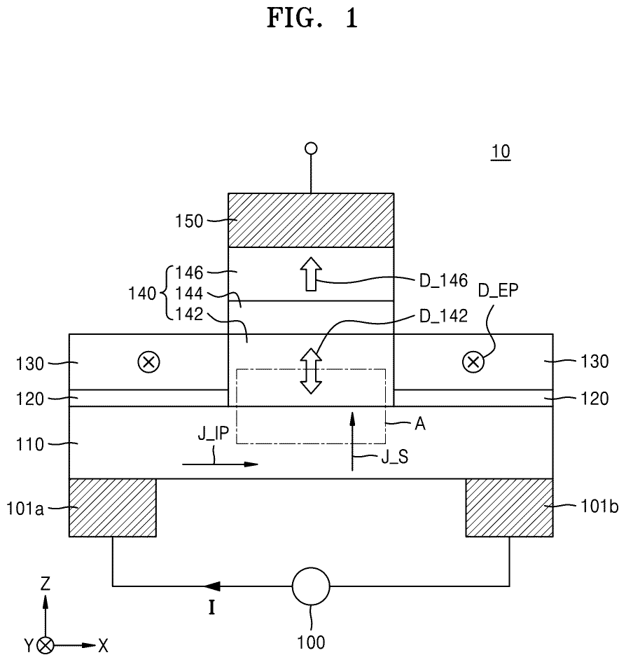

FIG. 1 is a cross-sectional view of a magnetic memory device according to some embodiments.

Referring to FIG. 1, a magnetic memory device 10 may include a magnetic tunnel junction (MTJ) structure 140. The MTJ structure 140 may include a free magnetic layer 142 configured to switch the direction of magnetization in a direction parallel to the vertical direction (+Z direction or −Z direction). The free magnetic layer 142 of the inventive concept may correspond to a free layer (of the magnetic memory device 10). The free magnetic layer 142 may form (may have) perpendicular magnetic anisotropy (PMA) having a preferred magnetic direction (e.g., the vertical direction) with respect to a particular direction. The free magnetic layer 142 may include a PMA material having PMA.

The MTJ structure 140 may further include a first insulation layer 144 on the free magnetic layer 142 and a pinned magnetic layer 146 on the first insulation layer 144. The resistance value of the MTJ structure 140 may vary depending on the magnetization direction of the free magnetic layer 142. When the magnetization direction of the free magnetic layer 142 is parallel with the magnetization direction of the pinned magnetic layer 146, the MTJ structure 140 may have a low (a lower) resistance value and store data ‘0’. When the magnetization direction of the free magnetic layer 142 is antiparallel with the magnetization direction of the pinned magnetic layer 146, the MTJ structure 140 may have a high (a higher) resistance value and store data ‘1’. Herein, parallel and antiparallel may be opposite directions to each other. When element A is parallel with element B, element A and element B extend in the same direction, and when element A is antiparallel with element B, element A and element B extend in opposite directions. For example, when element A extends in Z direction and element B is parallel with element A, element B also extends in Z direction. On the contrary, when element A extends in Z direction and element B is antiparallel with element A, element B extends in negative Z direction (−Z direction).

The free magnetic layer 142 may include, for example, iron (Fe), cobalt (Co), nickel (Ni), boron (B), silicon (Si), and/or zirconium (Zr). The pinned magnetic layer 146 may include, for example, Fe, Co, Ni, B, Si, and/or Zr. For example, the free magnetic layer 142 may include a PMA material stated above. According to embodiments, the free magnetic layer 142 may include, for example, Fe, Co, Ni, palladium (Pd), and/or platinum (Pt). The free magnetic layer 142 may include, for example, a Co-M1 alloy (where M1 is at least one metal selected from among Pt, Pd, and Ni) and/or an Fe-M2 alloy (where M2 is at least one metal selected from among Pt, Pd, and Ni). The Co-M1 alloy and/or the Fe-M2 alloy may have an L10 structure. According to other embodiments, the free magnetic layer 142 may further include, for example, B, carbon (C), copper (Cu), silver (Ag), gold (Au), ruthenium (Ru), tantalum (Ta), and/or chromium (Cr). According to embodiments, the free magnetic layer 142 may be formed to include a multilayer structure of, for example, (Co/Pt)m, (Co/Pd)m, and/or (Co/Ni)m (where m is a natural number).

The free magnetic layer 142 may have a first width in the first horizontal direction (X direction of FIG. 1) and have a second width in the direction in the second horizontal direction (Y direction of FIG. 1). According to embodiments, the first width and the second width of the free magnetic layer 142 may each be from (about) 2 nanometers (nm) to (about) 40 nm, but are not limited thereto.

The first insulation layer 144 may be formed on the free magnetic layer 142 to a certain thickness (in Z direction). For example, the first insulation layer 144 may have a thickness less than the spin diffusion length of the free magnetic layer 142. The first insulation layer 144 may include a non-magnetic material. According to embodiments, the first insulation layer 144 may include, for example, oxides of magnesium (Mg), titanium (Ti), aluminum (Al), magnesium-zinc (MgZn), and/or magnesium-boron (MgB). The first insulation layer 144 may (further) include, for example, nitrides of titanium (Ti) and/or vanadium (V). For example, the first insulation layer 144 may include a magnesium oxide (MgO) film. In some embodiments, the first insulation layer 144 may include a plurality of layers. For example, the first insulation layer 144 may include magnesium (Mg)/magnesium oxide (MgO), magnesium oxide (MgO)/magnesium (Mg), and/or magnesium (Mg)/magnesium oxide (MgO)/magnesium (Mg). According to embodiments, the first insulation layer 144 may have a certain crystal structure. For example, the first insulation layer 144 may have a NaCl crystal structure (face-centered cubic lattice structure).

The magnetic memory device 10 may include a ferroelectric layer 130 on (at least a portion of) a sidewall of the free magnetic layer 142, a non-magnetic conductive layer 110 disposed on a lower (e.g., a bottom) surface of the free magnetic layer 142 and extending in the first horizontal direction (X direction), and a power supply 100 including first electrodes 101a and 101b that are arranged on a lower (e.g., a bottom) surface of the non-magnetic conductive layer 110 and configured to supply power for generating an in-plane current J_IP to the non-magnetic conductive layer 110.

The non-magnetic conductive layer 110 may be configured to generate a spin current J_S, which travels (flows or moves) in the vertical direction (Z direction) by the spin hall effect, from the in-plane current J_IP.

A portion of an upper (e.g., a top) surface of the non-magnetic conductive layer 110 may be in contact with the lower (e.g., the bottom) surface of the free magnetic layer 142. The remaining portion of the upper surface of the non-magnetic conductive layer 110 that does not contact the lower surface of the free magnetic layer 142 may contact a lower (e.g., a bottom) surface of the second insulation layer 120 included in the magnetic memory device 10. The ferroelectric layer 130 included in the magnetic memory device 10 may be disposed to be spaced apart from the upper surface of the non-magnetic conductive layer 110 in the vertical direction (Z direction) (by the second insulation layer 120). The second insulation layer 120 may be disposed between the ferroelectric layer 130 and the non-magnetic conductive layer 110. The second insulation layer 120 may extend around (surround) (at least a portion of) the sidewalls of the free magnetic layer 142, and the thickness of the second insulation layer 120 in the vertical direction (Z direction) may be less than the thickness of the free magnetic layer 142 in the vertical direction (Z direction) and less than the thickness of the ferroelectric layer 130 in the vertical direction (Z direction). The spin current J_S may be transmitted only to the free magnetic layer 142 and may not be transmitted to the ferroelectric layer 130. The second insulation layer 120 may prevent the transmitting of the spin current J_S to the ferroelectric layer 130.

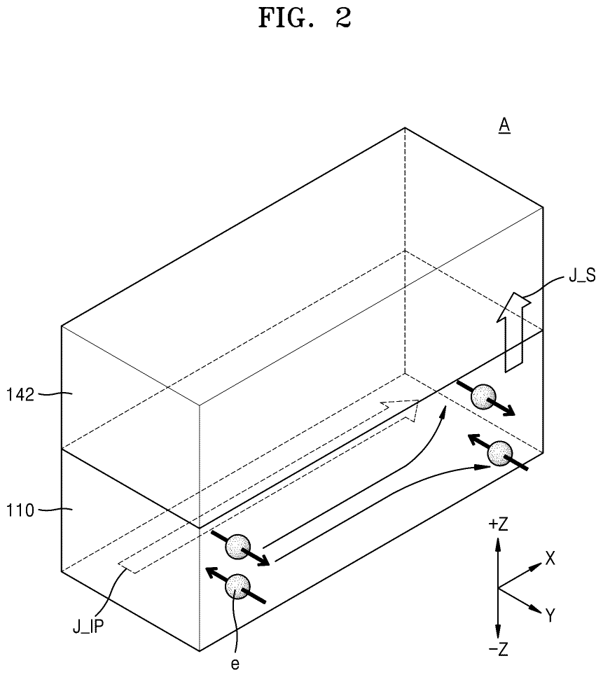

According to embodiments, the non-magnetic conductive layer 110 may include a material having a spin hall effect. The non-magnetic conductive layer 110 may (generate and) transmit the spin current J_S to the free magnetic layer 142 using the spin hall effect. For example, materials having the spin hall effect may be non-magnetic materials with a strong spin-orbit coupling characteristic. In a junction structure between a non-magnetic material with a strong spin-orbit coupling characteristic and a magnetic material, spin torque may be transmitted from the non-magnetic material with a strong spin-orbit coupling characteristic to the magnetic material, and the phenomenon may be called the spin hall effect. Meanwhile, a spin current transmission phenomenon due to the spin hall effect is described in detail below with reference to FIG. 2.

According to embodiments, the non-magnetic conductive layer 110 may include, for example, copper (Cu), tantalum (Ta), platinum (Pt), tungsten (W), titanium (Ti), bismuth (Bi), iridium (Ir), tantalum nitride (TaNx), and/or tungsten nitride (WNx). For example, the non-magnetic conductive layer 110 may include an alloy of tantalum (Ta), tungsten (W), platinum (Pt), and/or gold (Au) with other metal atoms. However, materials constituting the non-magnetic conductive layer 110 are not limited thereto and may also include other metal elements having a (giant) spin hall effect or alloys containing these elements.

The in-plane current J_IP flowing in the non-magnetic conductive layer 110 may travel (flow or move) in a direction parallel with the first horizontal direction (+X direction or −X direction). According to the inventive concept, the term ‘in-plane’ means existing inside the non-magnetic conductive layer 110 or being in the first horizontal direction (+X direction or −X direction), which may be the lengthwise direction of the non-magnetic conductive layer 110. The spin current J_S generated from the in-plane current J_IP by the non-magnetic conductive layer 110 may travel (flow or move) in the vertical direction (Z direction), and more particularly, travel (flow or move) from the lower (e.g., the bottom) surface of the non-magnetic conductive layer 110 toward the upper (e.g., top) surface of the non-magnetic conductive layer 110.

As described above, the spin current J_S may be transmitted only to the free magnetic layer 142 and may not be transmitted to the ferroelectric layer 130 due to the second insulation layer 120. The second insulation layer 120 may be formed on the non-magnetic conductive layer 110 to a certain thickness. For example, the second insulation layer 120 may have a thickness less than the spin diffusion length. The second insulation layer 120 may include a non-magnetic material. According to embodiments, the second insulation layer 120 may include, for example, oxides of magnesium (Mg), titanium (Ti), aluminum (Al), magnesium-zinc (MgZn), and/or magnesium-boron (MgB). The second insulation layer 120 may (further) include, for example, nitrides of titanium (Ti) and/or vanadium (V). For example, the second insulation layer 120 may include a magnesium oxide (MgO) film. In some embodiments, the second insulation layer 120 may include a plurality of layers. For example, the second insulation layer 120 may include magnesium (Mg)/magnesium oxide (MgO), magnesium oxide (MgO)/magnesium (Mg), and/or magnesium (Mg)/magnesium oxide (MgO)/magnesium (Mg). According to embodiments, the second insulation layer 120 may have a certain crystal structure. For example, the second insulation layer 120 may have a NaCl crystal structure (face-centered cubic lattice structure).

The electric polarization direction of the ferroelectric layer 130 may be the second horizontal direction (Y direction) orthogonal to the first horizontal direction (X direction) and the vertical direction (Z direction). The ferroelectric layer 130 may contact one surface (e.g., the upper surface) of the second insulation layer 120. The ferroelectric layer 130 may contact the side surfaces of the free magnetic layer 142. Side surfaces, herein, may refer to sidewalls.

The magnetization direction of the free magnetic layer 142 may be switched by lateral magnetization and the spin current J_S. The lateral magnetization may occur due to a surface magnetoelectric effect between the ferroelectric layer 130 and the free magnetic layer 142. Lateral magnetization ΔM may be formed on the side surfaces of the free magnetic layer 142 by the magnetoelectric effect corresponding to Equation 1 below.

$${μ}_{0} Δ M = {α}_{s} P \qquad [ Equation 1 ]$$

In [Equation 1], μ₀ denotes the vacuum permeability, ΔM denotes the lateral magnetization induced on the side surfaces of the free magnetic layer 142, αₛ denotes the interface magnetoelectric coefficient, and P denotes the electric polarization of the ferroelectric layer 130. The electrical polarization of the ferroelectric layer 130 may have ferroelectricity that does not become zero even without an external electric field, and switching does not occur due to an electric field caused by the in-plane current J_IP. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

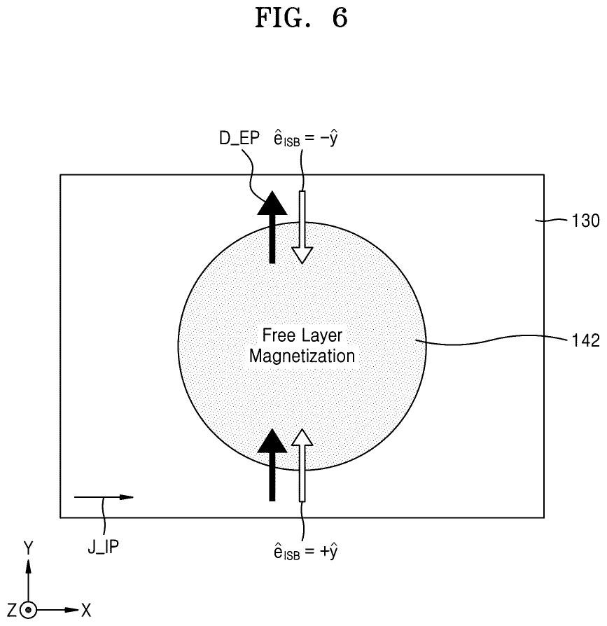

The direction of P may be parallel with the second horizontal direction (+Y direction or −Y direction), and the side magnetization ΔM of the free magnetic layer 142 that occurs due to the magnetoelectric effect may change the magnitude of the magnetization value of the side surfaces of the free magnetic layer 142. Detailed descriptions thereof are given below with reference to FIGS. 45, and 6. The lateral magnetization of the free magnetic layer 142 may allow switching of the free magnetic layer 142 due to a spin-orbit torque (SOT) to be used as a magnetic device capable of field-free switching that does not need application of an external magnetic field.

The ferroelectric layer 130 may include, for example, hafnium (Hf), barium (Ba), lead (Pb), zirconium (Zr), titanium (Ti), strontium (Sr), tantalum (Ta), tungsten (W), and/or europium (Eu). The vertical level of the upper (e.g., top) surface of the ferroelectric layer 130 may be identical to the vertical level of the upper (e.g., top surface) of the free magnetic layer 142. For example, the upper surface of the ferroelectric layer 130 may be coplanar with the upper surface of the free magnetic layer 142. The vertical level of the lower (e.g., bottom) surface of the ferroelectric layer 130 may not be identical to the vertical level of the (e.g., bottom) surface of the free magnetic layer 142. For example, the lower surface of the ferroelectric layer 130 may not be coplanar with the lower surface of the free magnetic layer 142. In detail, the lower (e.g., bottom) surface of the ferroelectric layer 130 may be formed to have a vertical level higher than the vertical level of the lower (e.g., bottom) surface of the free magnetic layer 142. Therefore, the thickness of the ferroelectric layer 130 in the vertical direction (Z direction) may be less than the thickness of the free magnetic layer 142 in the vertical direction (Z direction). For example, the upper surfaces of the ferroelectric layer 130 and the free magnetic layer 142 may be at the same distance in the vertical direction from the lower surface of the non-magnetic conductive layer 110. The lower surface of the ferroelectric layer 130 may be farther than the lower surface of the free magnetic layer 142 from the lower surface of the non-magnetic conductive layer 110 in the vertical direction.

The magnetic memory device 10 may include a second electrode 150 disposed on the upper (e.g., top) surface of the MTJ structure 140. The second electrode 150 may be configured to transmit signals.

FIG. 2 is an enlarged perspective view of a region A of FIG. 1.

Referring to FIG. 2 together with FIG. 1, the non-magnetic conductive layer 110 may include a plurality of electrons e. FIG. 2 schematically shows the spin current J_S generated by a current in a junction structure of a non-magnetic material and a magnetic material. After forming a stacked structure of the non-magnetic conductive layer 110 and the free magnetic layer 142, a current may flow in the longitudinal direction of the non-magnetic conductive layer 110 of the stacked structure (e.g., the lengthwise direction of the stacked structure or the first horizontal direction (X direction) of FIG. 2). The current may be supplied by the power supply 100, as described above. At this time, a current due to charge movement may be expressed as the in-plane current J_IP. Due to the strong spin-orbit coupling characteristic of the non-magnetic conductive layer 110, electrons with a spin (e.g., a first spin) may be deflected in the latitudinal direction of the non-magnetic conductive layer 110 (e.g., the a direction perpendicular to the lengthwise direction of the stacked structure or the vertical direction (+Z direction) of FIG. 2), and electrons with an opposite spin (e.g., a second spin that is opposite to the first spin) may be deflected in another direction (e.g., the vertical direction (−Z direction) of FIG. 2). For example, when a current flows in the first horizontal direction (+X direction or −X direction), up spin accumulates in the −Z direction and down spin accumulates in the +Z direction, and, by summing the accumulated spins, the spin current J_S may be generated in the +Z direction (or the −Z direction). In other words, when a current flows in the non-magnetic conductive layer 110, the spin current J_S may be induced in a direction perpendicular to the direction of the in-plane current J_IP, and spin torque may be transmitted to the free magnetic layer 142 in contact with the non-magnetic conductive layer 110. In other words, each spin direction of the plurality of electrons e included in the non-magnetic conductive layer 110 may be parallel with the second horizontal direction (+Y direction or −Y direction), and the spin current J_S generated by spins of the plurality of electrons e may travel (flow or move) in the vertical direction (Z direction) from the non-magnetic conductive layer 110 toward the free magnetic layer 142.

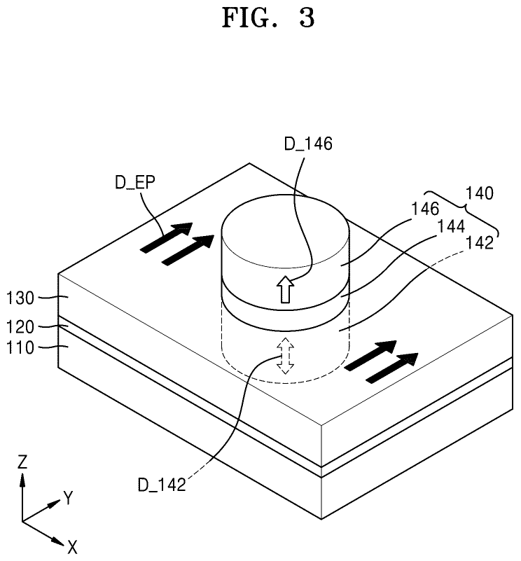

FIG. 3 is a perspective view of a magnetic memory device according to some embodiments.

Referring to FIG. 3 together with FIGS. 1 and 2, the cross-section of the MTJ structure 140 is shown as a circle in a plan view, but the shape of the cross-section of the MTJ structure 140 is not limited thereto. In a plan view, the widths (e.g., diameters) of the free magnetic layer 142, the first insulation layer 144, and the pinned magnetic layer 146 in the horizontal direction may be identical to one another. The vertical level of the lower (e.g., bottom) surface of the first insulation layer 144 may be identical to the vertical level of the upper (e.g., top) surface of the ferroelectric layer 130. For example, the lower surface of the first insulation layer 144 may be coplanar with the upper surface of the ferroelectric layer 130.

An electric polarization direction D_EP of the ferroelectric layer 130 may be parallel with the second horizontal direction (Y direction). In the diagram, the electric polarization direction D_EP is indicated as +Y direction, but it may be −Y direction depending on the direction of an input in-plane current J_IP or the direction of the spin current J_S.

A magnetization direction D_146 of the pinned magnetic layer 146 may be parallel with the vertical direction (Z direction), and more particularly, the pinned magnetic layer 146 may be magnetized in a direction from the lower (e.g., bottom) surface of the pinned magnetic layer 146 toward the upper (e.g., top) surface of the pinned magnetic layer 146 (e.g., in +Z direction). One side of the pinned magnetic layer 146 may contact the other side of the first insulation layer 144. The magnetization direction of the pinned magnetic layer 146 may be maintained stably. The pinned magnetic layer 146 may include a material of which the axis of easy magnetization is parallel with the vertical direction (Z direction). For example, the magnetization direction D_146 of the pinned magnetic layer 146 may be in an upward direction (+Z direction). However, the direction of the magnetization direction D_146 of the pinned magnetic layer 146 is not limited thereto. For example, the direction of the magnetization direction D_146 of the pinned magnetic layer 146 may be in −Z direction, depending on the conditions of other elements. A second electrode 150 is disposed on the upper (e.g., top) surface of the pinned magnetic layer 146, but illustration thereof is omitted. A magnetization direction D_142 of the free magnetic layer 142 may be parallel with the vertical direction (Z direction) and may be switched between an upward direction (+Z direction) and a downward direction (−Z direction). Thicknesses and shapes of components shown in the drawings are not limited thereto.

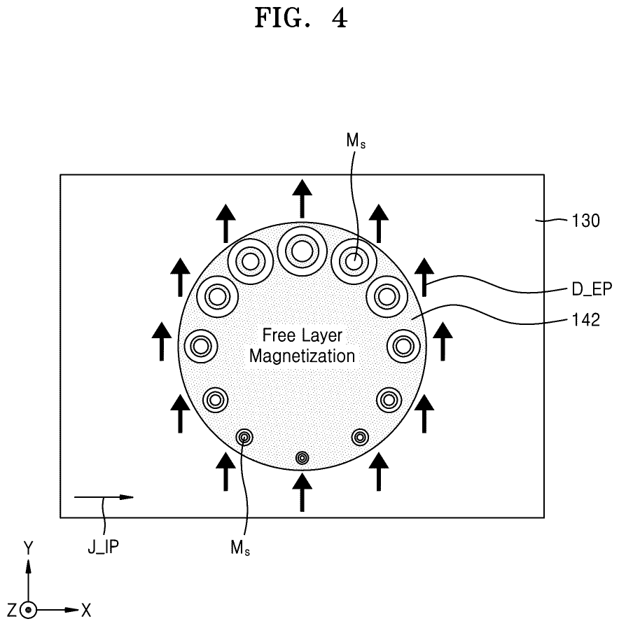

FIGS. 4, 5, and 6 are a plan views of a magnetic memory device according to some embodiments.

FIGS. 45, and 6 will be referred to together with FIGS. 1 to 3.

As shown in FIG. 4, in a plan view, the change ΔM in magnetization Mₛ may occur in the cross-section of the free magnetic layer 142 due to the electric polarization of the ferroelectric layer 130. In the drawings, the magnetization Mₛ including the change ΔM in the magnetization Mₛ is expressed as a vector in the +Z direction. The magnetization Mₛ may be expressed as a vector. The change ΔM in the magnetization Mₛ may be located at edges (e.g., circumference) of the free magnetic layer 142. As the in-plane current J_IP travels (flows or moves) in the +X direction and the electric polarization direction D_EP proceeds (towards) in the +Y direction, the magnetization Mₛ may increase in the edges (the circumference) of the free magnetic layer 142 in directions toward +Y direction. Also, conversely, as the in-plane current J_IP travels (flows or moves) in the +X direction and the electric polarization direction D_EP proceeds (towards) in the +Y direction, the magnetization Mₛ may decrease in the edges (the circumference) of the free magnetic layer 142 in directions toward −Y direction. Therefore, in a plan view, the magnitude of the lateral magnetization Mₛ of the free magnetic layer 142 may be asymmetrical around the central axis of the free magnetic layer 142 in the second horizontal direction (Y direction). Therefore, the conditions for field-free switching may be satisfied.

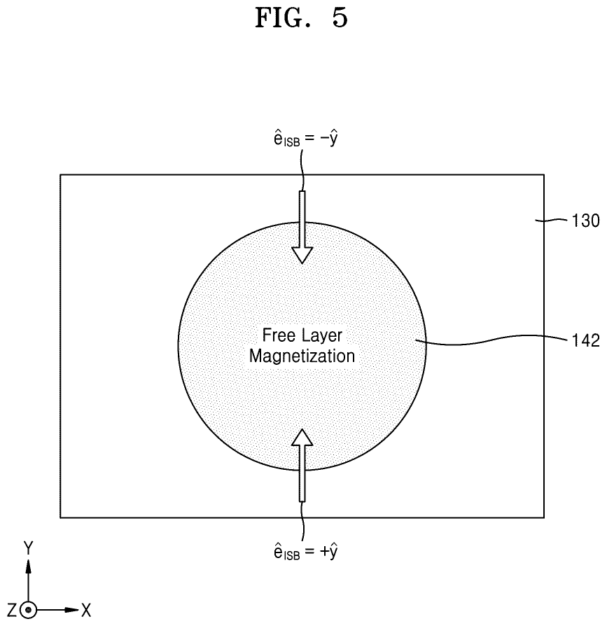

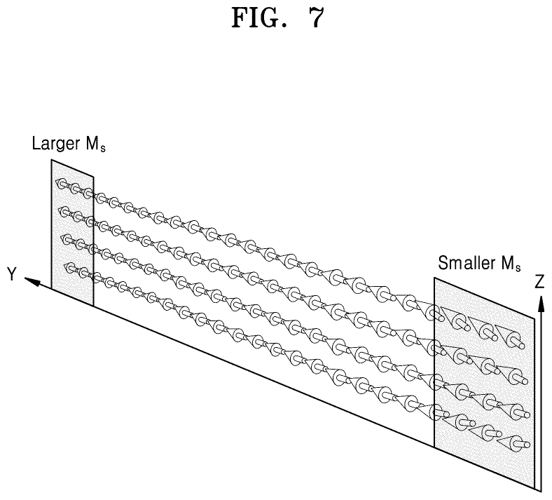

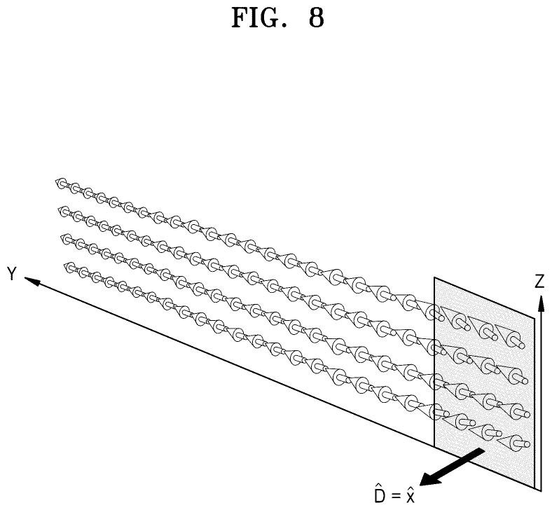

As shown in FIG. 5, a vector ê_{ISB} may be symmetrically determined in the vertical direction around the second horizontal direction (Y direction) by inversion symmetry breaking on the side surfaces (e.g., circumference) of the free magnetic layer 142. According to an embodiment, in a plan view, at the lower end (e.g., bottom end) of the free magnetic layer 142 in the second horizontal direction (Y direction), ê_{ISB} may be formed in the +Y direction. On the contrary, ê_{ISB} may be formed at the upper end (e.g., top end) of the second horizontal direction (Y direction) of the free magnetic layer 142 in the −Y direction. Inversion symmetry breaking may also occur in the first horizontal direction (X direction), but illustration thereof is omitted in the drawings. ê_{ISB} formed at the upper end and the lower end of the free magnetic layer 142 in the second horizontal direction (Y direction), respectively, may be symmetrically formed when there is no electric polarization by the ferroelectric layer 130. In the case of FIG. 6, inversion symmetry breaking by a built-in electric field by the ferroelectric layer 130 may be additionally considered. The built-in electric field by the ferroelectric layer 130 may correspond to the electric polarization described above, and a direction of the built-in electric field may correspond to the electric polarization direction D_EP. Considering ê_{ISB} and the electric field of the ferroelectric layer 130 together, vectors may offset each other at the upper end of the free magnetic layer 142 in the second horizontal direction (Y direction). For example, at the upper end of the free magnetic layer 142, ê_{ISB} may be in −Y direction, and the electric polarization direction D_EP may be +Y direction. On the other hand, at the lower end of the second horizontal direction (Y direction) of the free magnetic layer 142, the electric polarization direction D_EP may be identical to the direction of the +Y direction, and thus the sum of sizes of vectors thereof may be relatively large (larger). In other words, Dzyaloshinskii-Moriya Interaction (DMI) may be strongly applied only to one side surface (only a portion of the circumference) of the free magnetic layer 142 in the second horizontal direction (Y direction). According to the inventive concept, the DMI may occur when the inversion symmetry in a magnetic layer is broken as shown in FIG. 6 and an asymmetric structure is formed. The DMI may be a result of a spin-orbit interaction and mean a coupling between a spin motion and an electron-orbit motion, which causes magnetizations adjacent to each other to prefer directions perpendicular to each other. The DMI is described in detail with reference to FIGS. 7 and 8.

FIGS. 7 and 8 are diagrams showing the direction of magnetization of a free magnetic layer included in a magnetic memory device according to some embodiments. FIGS. 7 and 8 will be referred to together with FIGS. 1, 2, 3, 4, 5, and 6.

FIG. 7 shows the ferromagnetic system of the free magnetic layer 142 on the YZ plane. The free magnetic layer 142 may be disposed toward (may extend in) the second horizontal direction (Y direction) by the SOT. In the second horizontal direction Y, the magnitude of the magnetization Mₛ may be smaller in a region closer to the origin, and the magnitude of the magnetization Mₛ may be larger in a region away from (farther from) the origin. In the region close (closer) to the origin, the effective magnetic field of the effective PMA of the magnetization Mₛ may be larger, and thus switching may be performed in the region close (closer) to the origin before in the region far (farther) from the origin.

In the drawing, the vector of the free magnetic layer 142 is shown large (larger) at the origin (a region closer to the origin) and is shown small (smaller) in the region far (farther) from the origin, but the sizes are only perspective illustrations. Therefore, throughout the second horizontal direction (Y direction), the size of the vector of the free magnetic layer 142 may be the same and is not limited to the size shown in the drawing.

Referring to FIG. 8, in a region close (closer) to the origin (i.e., a region where the magnitude of the magnetization Mₛ is small (smaller)), the DMI may occur (e.g., the DMI may be stronger). The direction of the DMI D may be parallel to the direction of the third unit vector, which is the cross product of the first unit vector parallel with the vertical direction (e.g., +Z direction) and the second unit vector parallel with the direction of the electric polarization (e.g., +Y direction). In other words, the first unit vector parallel with the vertical direction (e.g., +Z direction) is expressed as \hat{d}, and the second unit vector parallel with the direction of electric polarization is expressed as ê_{ISB}. The direction of each unit vector is as shown in Equation 2 below.

$$\hat{d} = \hat{z} , {\hat{e}}_{ISB} = \hat{y} \qquad [ Equation 2 ]$$

In the present invention, the first unit vector, the second unit vector, and the third unit vector are newly defined to describe the DMI, the first unit vector and the above-stated first horizontal direction (X direction) may not necessarily correspond to each other, and the second unit vector may not necessarily correspond to the above-stated second horizontal direction (Y direction).

According to an embodiment, the direction of the DMI D may be obtained as in Equation 3 below.

$$\hat{D} = \hat{d} \times {\hat{e}}_{ISB} \qquad [ Equation 3 ]$$

Therefore, as shown in FIG. 8, the direction of the DMI D may be formed in the direction of \hat{x} parallel with the third unit vector (e.g., X direction), which is the cross product of the first unit vector and the second unit vector. When the magnetization is aligned in the +Y direction due to the SOT, the Z-axis (Z direction) component of the magnetization Mₛ may be generated due to the DMI. Therefore, it may be confirmed that, in a region close to the origin where the size of the magnetization Mₛ is smaller, some of the magnetization is distorted in the +Z direction or the −Z direction. The Z-axis (Z direction) component generated by the DMI may have different signs of distortion of the free magnetic layer 142 depending on signs of an injected spin, and the above-stated field-free switching may be performed.

In the drawing, the vector of the free magnetic layer 142 may be shown large (larger) at (a region closer to) the origin and may be shown small (smaller) in the region far (farther) from the origin, but the sizes are only perspective illustrations. Therefore, throughout the second horizontal direction (Y direction), the size of the vector of the free magnetic layer 142 may be the same and is not limited to the size shown in the drawing.

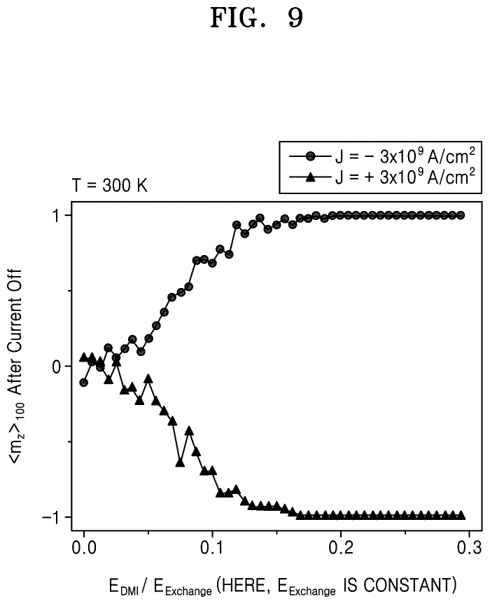

FIG. 9 is a graph showing an average value <m_{z}>₁₀₀ of values obtained by calculating an average value <m_{z}> of a vertical component of magnetization after a hundred (100) times of field-free switching according to the magnitude of the DMI.

m_{z} denotes the component of magnetization in the vertical direction (Z direction) considering thermal fluctuations, assuming that the magnitude of the magnetization vector in the free magnetic layer 142 is 1. <m_{z}> denotes an average value of m_{z} of all magnetizations in the free magnetic layer 142. <m_{z}>₁₀₀ means the average value of <m_{z}> calculated in a hundred (100) simulations.

Referring to FIG. 9 together with FIGS. 1, 2, 3, 4, 5, 6, 7, and 8, the X-axis represents values obtained by dividing energy E_{DMI} of the DMI by energy E_{Exchange} of an exchange interaction. However, in the inventive concept, for convenience of explanation, the energy E_{Exchange} of the exchange interaction is set as a constant. In the inventive concept, the energy E_{Exchange} of the exchange interaction denotes the force that favors the same direction between magnetizations adjacent to each other, as opposed to the DMI. The Y-axis represents the average value <m_{z}>₁₀₀ of the average values <m_{z}> of the vertical component of magnetization calculated a hundred (100) times in an off state where a current is not supplied (after a current was supplied).

The magnitude of a current J may be (may be the same as) 3×10⁹ A/cm², and the direction of the current J may be determined differently according to a sign of ±. Therefore, the current J of +3×10⁹ A/cm² and the current J of −3×10⁹ A/cm² may have the same magnitude and different directions.

According to an embodiment, when the current J is +3×10⁹ A/cm², the free magnetic layer 142 may be finally magnetized in the −Z direction. In other words, <m_{z}>₁₀₀ may finally have a value close to −1. On the contrary, when the current J is −3×10⁹ A/cm², the free magnetic layer 142 may be finally magnetized in the +Z direction. In other words, <m_{z}>₁₀₀ may finally have a value close to +1.

When <m_{z}>₁₀₀ is close to 1 or −1, the magnetization may be aligned in the +Z or −Z direction, and thus a field-free switching may occur. When the value of <m_{z}>₁₀₀ is greater than −0.97 and less than 0.97, it means that the magnetization is not definitely switched in any one direction. Referring to FIG. 9, it may be seen that the larger the magnitude of the DMI, the more field-free switching occurs.

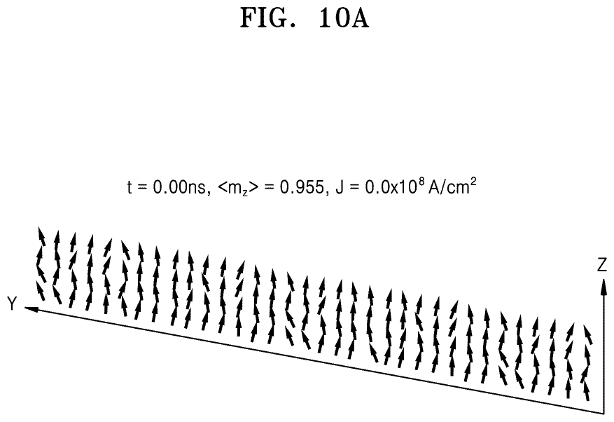

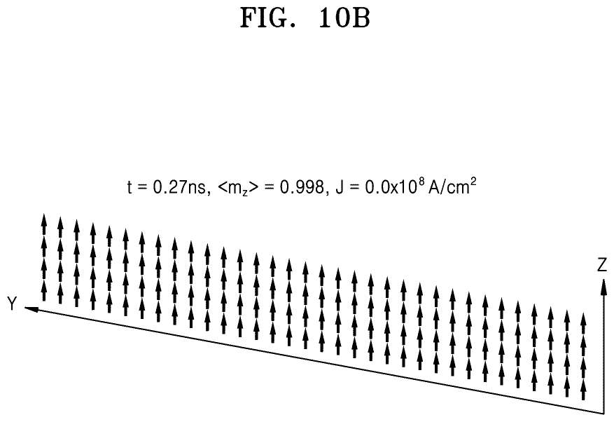

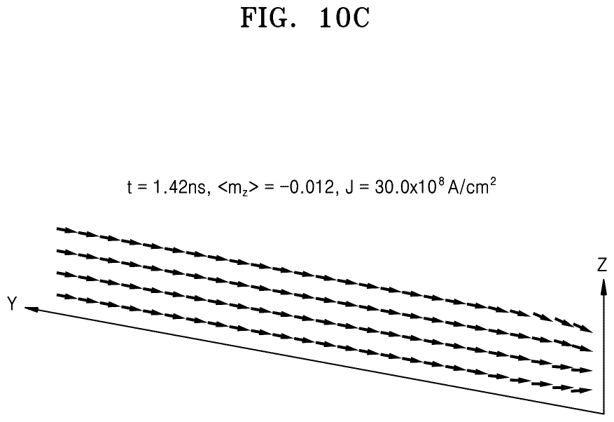

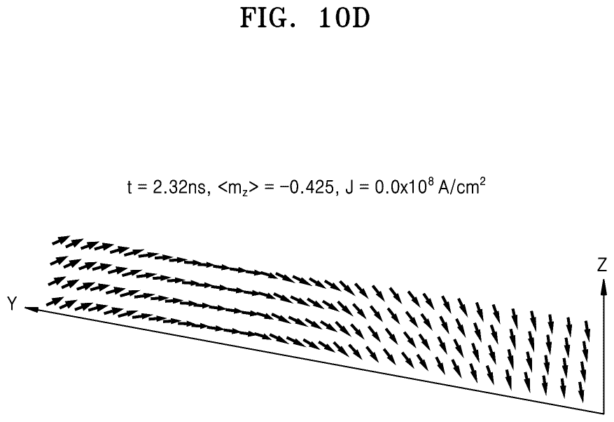

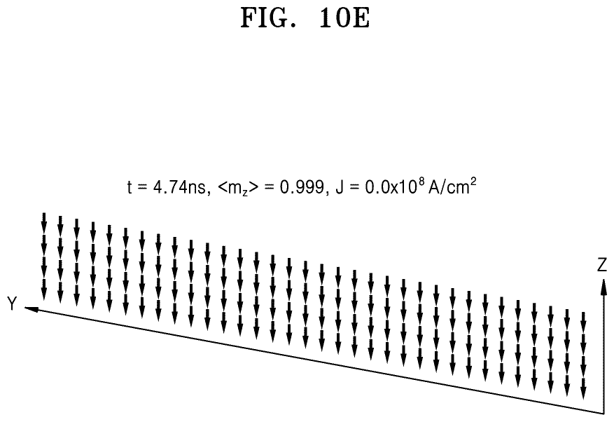

FIGS. 10A, 10B, 10C, 10D, and 10E are diagrams showing the direction of magnetization of a free magnetic layer included in a magnetic memory device according to some embodiments.

FIGS. 10A, 10B, 10C, 10D, and 10E will be described with reference to FIGS. 1, 2, 3, 4, 5, 6, 7, 8, and 9. FIG. 10A shows the magnetization state of the free magnetic layer 142 before a current is input to a non-magnetic conductive layer (e.g., the non-magnetic conductive layer 110). Since the value of <m_{z}> is 0.955, which is close to +1, most of the magnetization may be directed in the +Z direction. However, it may be confirmed that the magnetization is overall aligned to +Z and is not exactly aligned in the same direction. It may be seen that the error of the alignment corresponds to a value obtained by subtracting 0.955 from +1, that is, 0.045. FIG. 10B shows the state after 0.27 nano-seconds (ns) have elapsed, and it may be seen that the magnetization is relatively more aligned (<m_{z}> is 0.998) in the +Z direction than in FIG. 10A. FIG. 10C shows the state after 1.42 ns have elapsed, in which a current is applied to 3×10⁹ A/cm². Therefore, the magnetization of the free magnetic layer 142 may be aligned toward a direction parallel with the second horizontal direction (Y direction), and the value of <m_{z}> may be formed to be −0.012, which is close to 0. However, even when aligned parallel with the second horizontal direction (Y direction), in a region close to the origin, some vectors may be distorted by adding +Z direction or −Z direction components thereto. It may be seen that the degree of distortion corresponds to misalignment by the value of <m_{z}>, that is, −0.012. The number of distorted vectors and the degrees of distortion thereof shown in FIG. 10C are not limited thereto. FIG. 10D shows the state after 2.32 ns have elapsed, which is an off state where a current is no longer input the non-magnetic conductive layer (the non-magnetic conductive layer 110). The value of <m_{z}> may fall in the range from −0.97 to 0.97 (e.g., −0.425 in FIG. 10D), meaning that the magnetization in the region is not aligned. Also, as shown in FIG. 9, it may be confirmed that field-free switching is progressing primarily toward the −Z direction in a region close (closer) to the origin on the YZ plane. On the other hand, it may be seen that field-free switching does not proceed in a region far (farther) from the origin, and magnetization is performed in disordered directions. FIG. 10E shows the state after 4.74 ns have elapsed, and it may be confirmed that field-free switching is performed in all regions of the free magnetic layer 142 to be aligned in the −Z direction. The times, the values, etc. in FIGS. 9, 10A, 10B, 10C, 10D, and 10E are only examples of a simulation and are not limited thereto.

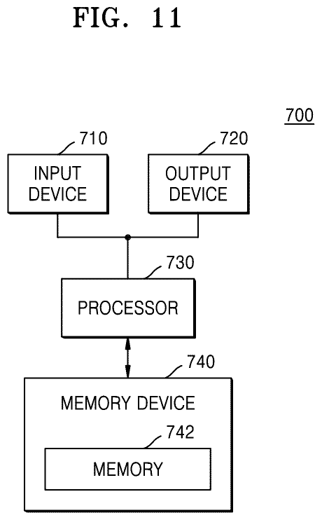

FIG. 11 is a block diagram showing an information processing system including a magnetic memory device according to some embodiments.

Referring to FIG. 11, an information processing system 700 includes an input device 710, an output device 720, a processor 730, and a memory device 740. According to some embodiments, the memory device 740 may include a cell array including non-volatile memory cells and a peripheral circuit for operations such as read/write. According to some embodiments, the memory device 740 may include a non-volatile memory device and a memory controller.

A memory 742 included in the memory device 740 may include the MTJ structure 140 or the magnetic memory device 10 including the MTJ structure 140, according to the embodiments described above with reference to FIGS. 1, 2, 3, 4, 5, 6, and 7.

The processor 730 may be (electrically) connected to the input device 710, the output device 720, and the memory device 740 through an interface and may control overall operations of the information processing system 700.

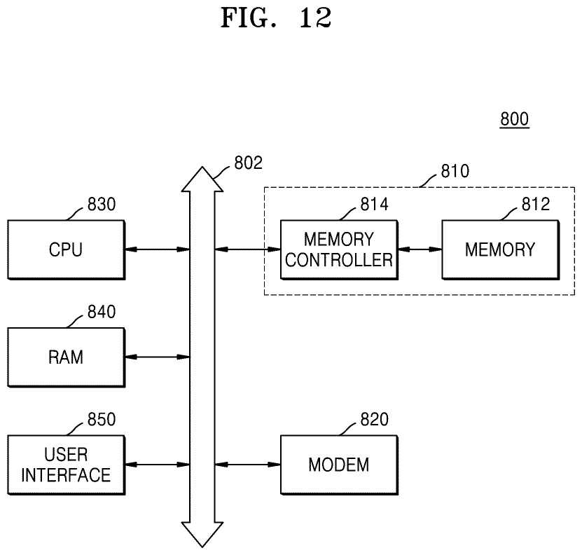

FIG. 12 is a block diagram showing an electronic system including a magnetic memory device according to some embodiments.

Referring to FIG. 12, an electronic system 800 includes a non-volatile memory system 810, a modem 820, a central processing unit (CPU) 830, RAM 840, and a user interface 850 that are electrically connected to a bus 802.

The non-volatile memory system 810 may include a memory 812 and a memory controller 814. The non-volatile memory system 810 may store data processed by the CPU 830 or data input from the outside.

The non-volatile memory system 810 may include a non-volatile memory such as magnetic RAM (MRAM), phase-change RAM (PRAM), resistive RAM (RRAM), and ferroelectric RAM (FRAM). At least one of the memory 812 and the RAM 840 may include the MTJ structure 140 or the magnetic memory device 10 including the MTJ structure 140, according to the embodiments described above with reference to FIGS. 1, 2, 3, 4, 5, 6, and 7.

The electronic system 800 may be used in a portable computer, a web tablet, a wireless phone, a mobile phone, a digital music player, a memory card, an MP3 player, a navigation, a portable multimedia player (PMP), a solid state disk (SSD), or a household appliance.

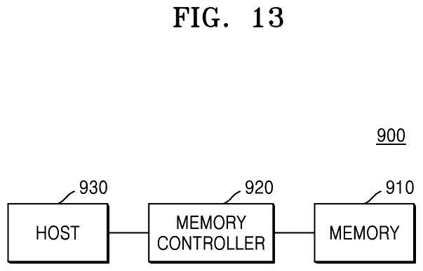

FIG. 13 is a block diagram showing a memory card including a magnetic memory device according to some embodiments.

A memory card 900 may include a memory 910 and a memory controller 920.

The memory 910 may store data. According to some embodiments, the memory 910 has non-volatile characteristics to retain stored data even when power supply is interrupted. The memory 910 may include the MTJ structure 140 or the magnetic memory device 10 including the structure 140 according to the embodiments described above with reference to FIGS. 1, 2, 3, 4, 5, 6, and 7.

The memory controller 920 may read data stored in the memory 910 or store data in the memory 910 in response to a read/write request from a host 930.

While the inventive concept has been particularly shown and described with reference to embodiments thereof, it will be understood that various changes in form and details may be made therein without departing from the scope of the following claims.

What is claimed is:

1. A magnetic memory device comprising:
a free magnetic layer configured to switch a direction of magnetization between a first direction and a second direction that are opposite to each other, wherein the first direction and the second direction are perpendicular to an upper surface and/or a lower surface of the free magnetic layer;
a first insulation layer on the free magnetic layer;
a ferroelectric layer on at least a portion of side surfaces of the free magnetic layer; and
a non-magnetic conductive layer on the lower surface of the free magnetic layer,
wherein the magnetic memory device further comprises a power supply configured to supply power to the non-magnetic conductive layer to generate an in-plane current,
wherein the non-magnetic conductive layer is configured to generate a spin current in the first direction by a spin hall effect from the in-plane current,
wherein an upper surface of the ferroelectric layer is coplanar with the upper surface of the free magnetic layer, and a lower surface of the ferroelectric layer is not coplanar with the lower surface of the free magnetic layer, and
wherein an electric polarization direction of the ferroelectric layer is a third direction parallel with the upper surface and/or the lower surface of the free magnetic layer.

2. The magnetic memory device of claim 1, wherein the free magnetic layer is configured to have a magnetization direction that is switched by a lateral magnetization and the spin current,
wherein the ferroelectric layer and the free magnetic layer are configured to have a surface magnetoelectric effect therebetween, and
wherein the surface magnetoelectric effect causes the lateral magnetization.

3. The magnetic memory device of claim 2, wherein, in a plan view, a magnitude of the lateral magnetization of the free magnetic layer is asymmetric around a central axis of the free magnetic layer in the third direction.

4. The magnetic memory device of claim 3, wherein, in a plan view, a first portion of the side surfaces of the free magnetic layer has a greater magnitude of the lateral magnetization than that of a second portion of the side surfaces of the free magnetic layer,
wherein the second portion of the side surfaces of the free magnetic layer has Dzyaloshinskii-Moriya interaction (DMI) in the third direction, and
wherein a direction of the DMI is parallel with a first unit vector, which is a cross product of a second unit vector parallel with the first direction or the second direction and a third unit vector parallel with the electric polarization direction.

5. The magnetic memory device of claim 1, wherein the in-plane current flows parallel with a fourth direction,
wherein the fourth direction is parallel with the upper surface and/or the lower surface of the free magnetic layer,
wherein the fourth direction is perpendicular to the third direction,
wherein each spin direction of a plurality of electrons included in the non-magnetic conductive layer is parallel with the third direction, and
wherein a spin current generated by spins of the plurality of electrons flows in the first direction from the non-magnetic conductive layer toward the free magnetic layer.

6. The magnetic memory device of claim 1, wherein the ferroelectric layer extends around the side surfaces of the free magnetic layer.

7. The magnetic memory device of claim 1, wherein the ferroelectric layer is spaced apart from an upper surface of the non-magnetic conductive layer in the first direction, and
wherein the magnetic memory device further comprises a second insulation layer between the ferroelectric layer and the non-magnetic conductive layer.

8. The magnetic memory device of claim 7, wherein the second insulation layer extends around the side surfaces of the free magnetic layer, and
wherein a thickness of the second insulation layer in the first direction is less than a thickness of each of the free magnetic layer and the ferroelectric layer in the first direction.

9. The magnetic memory device of claim 1, wherein, in a plan view, widths of the free magnetic layer and the first insulation layer are equal.

10. The magnetic memory device of claim 1, further comprising: a pinned magnetic layer on the first insulation layer,
wherein a magnetization direction of the pinned magnetic layer is the first direction.

11. A magnetic memory device comprising:
a non-magnetic conductive layer extending in a first direction and comprising a material having a spin hall effect;
a power supply on a lower surface of the non-magnetic conductive layer, configured to supply power for generating an in-plane current to the non-magnetic conductive layer, and comprising a first electrode;
a magnetic tunnel junction (MTJ) structure on at least a portion of an upper surface of the non-magnetic conductive layer; and
a ferroelectric layer on at least a portion of side surfaces of the MTJ structure,
wherein the non-magnetic conductive layer is configured to generate a spin current in a second direction by a spin hall effect from the in-plane current,
wherein the first direction is parallel with the lower surface of the non-magnetic conductive layer, and the second direction is perpendicular to the lower surface of the non-magnetic conductive layer,
wherein the MTJ structure comprises:
a free magnetic layer on the non-magnetic conductive layer; and
a first insulation layer on the free magnetic layer,
wherein an electric polarization direction of the ferroelectric layer is a third direction perpendicular to the first direction and the second direction,
wherein the free magnetic layer is configured to have a magnetization direction that is switched in the second direction and a fourth direction opposite to the second direction by a lateral magnetization and the spin current, and
wherein the ferroelectric layer and the free magnetic layer are configured to cause the lateral magnetization therebetween by a surface magnetoelectric effect.

12. The magnetic memory device of claim 11, wherein a material with a spin hole effect included in the non-magnetic conductive layer comprises copper (Cu), tantalum (Ta), platinum (Pt), tungsten (W), titanium (Ti), bismuth (Bi), iridium (Ir), tantalum nitride (TaNx), and/or tungsten nitride (WNx).

13. The magnetic memory device of claim 11, wherein the free magnetic layer comprises iron (Fe), cobalt (Co), nickel (Ni), boron (B), silicon (Si), and/or zirconium (Zr).

14. The magnetic memory device of claim 11, wherein the ferroelectric layer comprises hafnium (Hf), barium (Ba), lead (Pb), zirconium (Zr), titanium (Ti), strontium (Sr), tantalum (Ta), tungsten (W), and/or europium (Eu).

15. The magnetic memory device of claim 11, wherein the ferroelectric layer is spaced apart from the upper surface of the non-magnetic conductive layer in the second direction,
wherein the magnetic memory device further comprises a second insulation layer between the ferroelectric layer and the non-magnetic conductive layer,
wherein the second insulation layer extends around side surfaces of the free magnetic layer, and
wherein a thickness of the second insulation layer in the second direction is less than a thickness of each of the free magnetic layer and the ferroelectric layer in the second direction.

16. The magnetic memory device of claim 11, further comprising: a second electrode on an upper surface of the MTJ structure,
wherein the MTJ structure comprises a pinned magnetic layer on the first insulation layer, and
wherein a magnetization direction of the pinned magnetic layer is the second direction from the first insulation layer toward the second electrode.

17. The magnetic memory device of claim 11, wherein, in a plan view, a magnitude of the lateral magnetization of the free magnetic layer is asymmetric around a central axis of the free magnetic layer in the third direction,
wherein a first portion of side surfaces of the free magnetic layer in the third direction has a greater magnitude of the lateral magnetization than a second portion of the side surfaces of the free magnetic layer in the third direction,
wherein the second portion of the side surfaces of the free magnetic layer has Dzyaloshinskii-Moriya Interaction (DMI), and
wherein a direction of the DMI is parallel with a first unit vector, which is a cross product of a first unit vector parallel with the second direction and a second unit vector parallel with the electric polarization direction.

18. The magnetic memory device of claim 11, wherein the in-plane current flows in a direction parallel with the first direction,
wherein each spin direction of a plurality of electrons included in the non-magnetic conductive layer is parallel with the third direction, and
wherein a spin current generated by spins of the plurality of electrons flows in the second direction from the non-magnetic conductive layer toward the free magnetic layer.

19. A magnetic memory device comprising:
a non-magnetic conductive layer extending in a first direction and comprising a material having a spin hall effect;
a power supply on a lower surface of the non-magnetic conductive layer, configured to supply power for generating an in-plane current to the non-magnetic conductive layer, and comprising a first electrode;
a magnetic tunnel junction (MTJ) structure on at least a portion of an upper surface of the non-magnetic conductive layer; and
a ferroelectric layer on at least a portion of side surfaces of the MTJ structure,
wherein the non-magnetic conductive layer is configured to generate a spin current in a second direction by a spin hall effect from the in-plane current,
wherein the first direction is parallel with the lower surface of the non-magnetic conductive layer, and the second direction is perpendicular to the lower surface of the non-magnetic conductive layer,
the MTJ structure comprises:
a free magnetic layer on the non-magnetic conductive layer; and
a first insulation layer on the free magnetic layer,
wherein an electric polarization direction of the ferroelectric layer is a third direction perpendicular to the first direction and the second direction,
wherein the free magnetic layer is configured to have a magnetization direction that is switched in the second direction and a fourth direction opposite to the second direction by a lateral magnetization and the spin current,
wherein the ferroelectric layer and the free magnetic layer are configured to cause the lateral magnetization therebetween by a surface magnetoelectric effect,
wherein the ferroelectric layer is spaced apart from an upper surface of the non-magnetic conductive layer in the second direction,
wherein the magnetic memory device further comprises a second insulation layer between the ferroelectric layer and the non-magnetic conductive layer,
wherein the second insulation layer extends around side surfaces of the free magnetic layer, and
wherein a thickness of the second insulation layer in the second direction is less than a thickness of each of the free magnetic layer and the ferroelectric layer in the second direction.

20. The magnetic memory device of claim 19, wherein, in a plan view, a magnitude of the lateral magnetization of the free magnetic layer is asymmetric around a central axis of the free magnetic layer in the third direction,
wherein a first portion of the side surfaces of the free magnetic layer in the third direction has a greater magnitude of the lateral magnetization than a second portion of the side surfaces of the free magnetic layer in the third direction,
wherein the second portion of the side surfaces of the free magnetic layer has Dzyaloshinskii-Moriya Interaction (DMI),
wherein a direction of the DMI is parallel with a first unit vector, which is a cross product of a second unit vector parallel with the second direction and a third unit vector parallel with the electric polarization direction,
wherein the in-plane current flows in a direction parallel to the first direction,
wherein each spin direction of a plurality of electrons included in the non-magnetic conductive layer is parallel with the third direction, and
wherein a spin current generated by spins of the plurality of electrons flows in the second direction from the non-magnetic conductive layer toward the free magnetic layer.
